(19) United States
(12) Patent Application Publication
(10) Pub. No.: US 2019/0081044 A1
(43) Pub. Date: Mar. 14, 2019

(54) SEMICONDUCTOR DEVICE HAVING SUB REGIONS TO DEFINE THRESHOLD VOLTAGES

(71) Applicant: Intel Corporation, Santa Clara, CA (US)

(72) Inventors: Uygar E. AVCI, Portland, OR (US); Raseong KIM, Portland, OR (US); Ian A. YOUNG, Portland, OR (US)

(21) Appl. No.: 16/080,974

(22) PCT Filed: Apr. 1, 2016
(86) PCT No.: PCT/US2016/025756

§ 371 Date: Aug. 29, 2018

(51) Int. Cl. H01L 27/092; H01L 29/66; H01L 29/78; H01L 29/08; H01L 29/10; H01L 29/51; H01L 21/22; H01L 21/8238

(52) U.S. Cl. CPC H01L 27/092; H01L 29/6659; H01L 29/7834; H01L 29/0847; H01L 29/1033; H01L 29/6656; H01L 21/22; H01L 21/823828; H01L 21/823814; H01L 21/823807; H01L 21/823864; H01L 29/517

(57) ABSTRACT

Embodiments of the present disclosure describe a semiconductor device having sub regions or distances to define threshold voltages. A first semiconductor device includes a first gate stack having a first edge opposing a second edge and a first source region disposed on the semiconductor substrate. A second semiconductor device includes a second gate stack having a third edge opposing a fourth edge and a second source region disposed on the semiconductor substrate. A first distance extends from the first source region to the first edge of the first gate stack and a second distance different from the first distance extends from the second source region to the third edge of the second gate stack.

### FIELD

Embodiments of the present disclosure generally relate to the field of integrated circuits and, more particularly, to a semiconductor device having sub regions to define threshold voltages.

### BACKGROUND

A threshold voltage (Vₜₕ) may impact leakage and switching speed of a semiconductor device. Emerging circuits may utilize devices with multiple threshold voltages to optimize power dissipation and dock frequency. In some instances, subcircuitry that constrains circuit performance may use lower Vₜₕ devices to increase switching speed and subcircuitry that does not constrain circuit performance may use higher Vₜₕ transistors to reduce power consumption. Traditional methods of modulating the threshold voltage of a device may be based on doping a channel region with different amounts of impurities. An exemplary n-type device may have a higher Vₜₕ if a greater number of p-type dopants are implanted into the channel. When the channels of different transistors are implanted with different dopant levels, different threshold voltages may be realized. Doping the channel, however, may adversely affect the switching speed of a transistor for a given leakage level. Dopant atoms may scatter mobile charge carriers reducing carrier charge mobility. Additionally, device performance variation may increase with increasing dopant levels. Unacceptable variation in Vₜₕ may increase with increased dopant levels due to random dopant fluctuations. And as the scale of devices shrinks with newer manufacturing technologies, channel doping becomes less effective to control Vₜₕ particularly where it is desirable to have an integrated circuit with devices operating at multiple voltage threshold targets.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1A schematically illustrates a top view of an example die in wafer form and in singulated form, in accordance with some embodiments.

FIG. 1B schematically illustrates a cross-section side view of an integrated circuit (IC) assembly, in accordance with some embodiments.

FIG. 2 schematically illustrates a cross section of an exemplary semiconductor device, in accordance with some embodiments.

FIG. 3A schematically illustrates a cross section of an exemplary semiconductor device, in accordance with some embodiments.

FIG. 3B schematically illustrates a cross section of an exemplary semiconductor device, in accordance with some embodiments.

FIG. 4A schematically illustrates a cross section of an exemplary semiconductor device, in accordance with some embodiments.

FIG. 4B schematically illustrates a cross section of an exemplary semiconductor device, in accordance with some embodiments.

FIG. 5A schematically illustrates a cross section of an exemplary semiconductor integrated circuit, in accordance with some embodiments.

FIG. 5B schematically illustrates a cross section of an exemplary semiconductor integrated circuit, in accordance with some embodiments.

FIGS. 6A-6B schematically illustrate a flow diagram for a method of fabricating semiconductor devices with various threshold voltages, in accordance with some embodiments.

FIG. 7 schematically illustrates an example system that may include transistor devices with various threshold voltages as described herein, in accordance with some embodiments.

### DETAILED DESCRIPTION

Embodiments of the present disclosure describe a semiconductor device having sub regions to define threshold voltages and associated techniques and configurations. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, side, over/under, and the like. Such descriptions are merely used to facilitate the discussion and are not intended to restrict the application of embodiments described herein to any particular orientation.

The description may use the phrases “in an embodiment,” or “in embodiments,”which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein, “Coupled” may mean one or more of the following. “Coupled may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

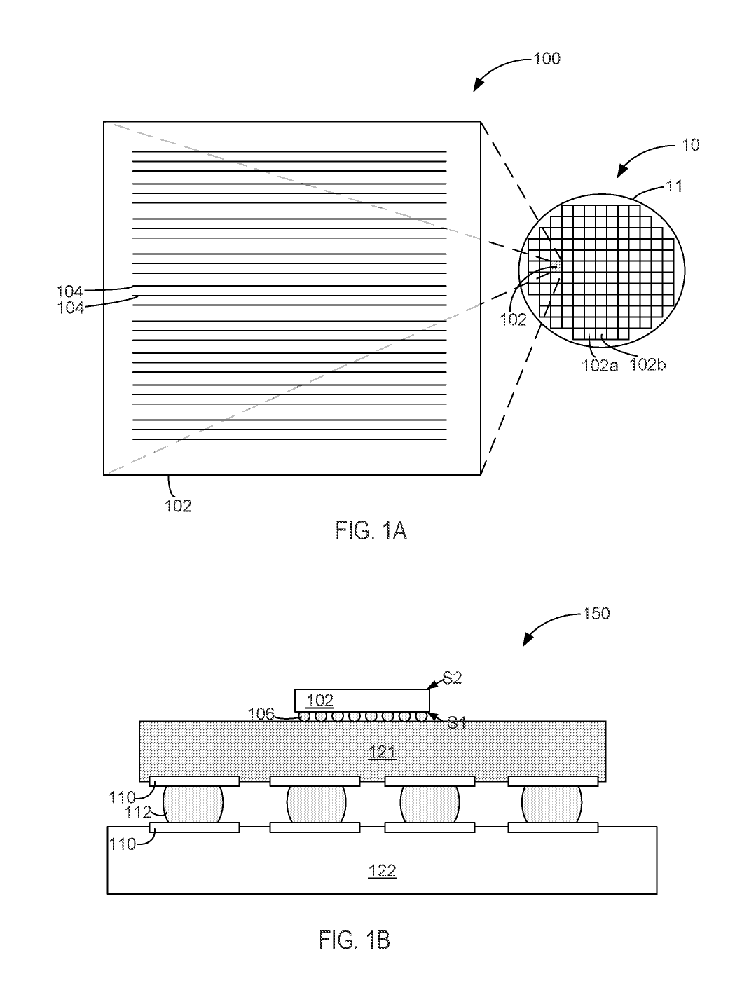

FIG. 1A schematically illustrates a top view of an example die 102 in a wafer form 10 and in a singulated form 100, in accordance with some embodiments. In some embodiments, die 102 may be one of a plurality of dies, e.g., dies 102, 102a, 102b, of a wafer 11 comprising semiconductor material, e.g., silicon or other suitable material. The plurality of dies, e.g., dies 102, 102a, 102b, may be formed on a surface of wafer 11. Each of the dies 102, 102a, 102b, may be a repeating unit of a semiconductor product that includes devices as described herein. For example, die 102 may include circuitry having transistor elements such as, for example, one or more channel bodies 104 (e.g., fin structures, nanowires, and the like) that provide a channel pathway for mobile charge carriers in transistor devices. Although one or more channel bodies 104 are depicted in rows that traverse a substantial portion of die 102, it is to be understood that one or more channel bodies 104 may be configured in any of a wide variety of other suitable arrangements on die 102 in other embodiments.

After a fabrication process of the device embodied in the dies is complete, wafer 11 may undergo a singulation process in which each of dies, e.g., die 102, is separated from one another to provide discrete “chips” of the semiconductor product. Wafer 11 may be any of a variety of sizes. In some embodiments, wafer 11 has a diameter ranging from about 25.4 mm to about 450 mm. Wafer 11 may include other sizes and/or other shapes in other embodiments. According to various embodiments, the one or more channel bodies 104 may be disposed on a semiconductor substrate in wafer form 10 or singulated form 100. One or more channel bodies 104 described herein may be incorporated in die 102 for logic, memory, or combinations thereof. In some embodiments, one or more channel bodies 104 may be part of a system-on-chip (SoC) assembly.

FIG. 1B schematically illustrates a cross-section side view of an integrated circuit (IC) assembly 150, in accordance with some embodiments. In some embodiments, IC assembly 150 may include one or more dies, e.g., die 102, electrically or physically coupled with a package substrate 121. Die 102 may include one or more channel bodies 104 that serve as channel bodies of multi-threshold voltage transistor devices as described herein. In some embodiments, package substrate 121 may be electrically coupled with a circuit board 122 as is well known to a person of ordinary skill in the art.

Die 102 may represent a discrete product made from a semiconductor material (e.g., silicon) using semiconductor fabrication techniques such as thin film deposition, lithography, etching, and the like used in connection with forming Complementary Metal Oxide Semiconductor (CMOS) devices. In some embodiments, die 102 may be, include, or be a part of a processor, memory, SoC or ASIC in some embodiments. In some embodiments, an electrically insulative material such as, for example, molding compound or underfill material (not shown) may encapsulate at least a portion of die 102 and/or die-level interconnect structures 106.

Die 102 can be attached to package substrate 121 according to a wide variety of suitable configurations including, for example, being directly coupled with package substrate 121 in a flip-chip configuration, as depicted. In the flip-chip configuration, an active side S1 of die 102 including circuitry is attached to a surface of package substrate 121 using die-level interconnect structures 106 such as bumps, pillars, or other suitable structures that may also electrically couple die 102 with package substrate 121. Active side S1 of die 102 may include multi-threshold voltage transistor devices as described herein. An inactive side S2 of die 102 may be disposed opposite to active side S1.

In some embodiments, die-level interconnect structures 106 may be configured to route electrical signals between die 102 and other electrical devices. The electrical signals may include, for example, input/output (I/O) signals and/or power/ground signals that are used in connection with operation of die 102.

In some embodiments, package substrate 121 is an epoxy-based laminate substrate having a core and/or build-up layers such as, for example, an Ajinomoto Build-up Film (ABF) substrate. Package substrate 121 may include other suitable types of substrates in other embodiments including, for example, substrates formed from glass, ceramic, or semiconductor materials.

Package substrate 121 may include electrical routing features configured to route electrical signals to or from die 102. The electrical routing features may include pads or traces (not shown) disposed on one or more surfaces of package substrate 121 and/or internal routing features (not shown) such as trenches, vias, or other interconnect structures to route electrical signals through package substrate 121. In some embodiments, package substrate 121 may include electrical routing features such as pads (not shown) configured to receive the respective die-level interconnect structures 106 of die 102.

Circuit board 122 may be a printed circuit board (PCB) comprising an electrically insulative material such as an epoxy laminate, Circuit board 122 may include electrically insulating layers composed of materials such as, for example, polytetrafluoroethylene, phenolic cotton paper materials such as Flame Retardant 4 (FR-4), FR-1, cotton paper and epoxy materials such as CEM-1 or CEM-3, or woven glass materials that are laminated together using an epoxy resin prepreg material. Interconnect structures such as traces, trenches, vias may be formed through the electrically insulating layers to route the electrical signals of die 102 through circuit board 122. Circuit board 122 may comprise other suitable materials in other embodiments. In some embodiments, circuit board 122 is a motherboard as is well known to a person of ordinary skill in the art.

Package-level interconnects such as, for example, solder balls 12 may be coupled to one or more pads 110 on package substrate 121 and/or on circuit board 122 to form corresponding solder joints that are configured to further route the electrical signals between package substrate 121 and circuit board 122. Pads 110 may comprise any suitable electrically conductive material such as metal including, for example, nickel (Ni), palladium (Pd), gold (Au), silver (Ag), copper (Cu), and combinations thereof. Other suitable techniques to physically and/or electrically couple package substrate 121 with circuit board 122 may be used in other embodiments.

IC assembly 150 may include a wide variety of other suitable configurations in other embodiments including, for example, suitable combinations of flip-chip and/or wire-bonding configurations, interposers, multi-chip package configurations including system-in-package (SiP), and/or package-on-package (PoP) configurations. Other suitable techniques to route electrical signals between die 102 and other components of IC assembly 150 may be used in some embodiments.

The following describe fabrication processes for semiconductor devices, particularly Field Effect Transistor (FET) devices fabricated using Complementary Metal Oxide Semiconductor (CMOS) processes. A person of ordinary skill in the art should recognize that any known semiconductor device fabricated using any known semiconductor process that may benefit from the principles described herein,

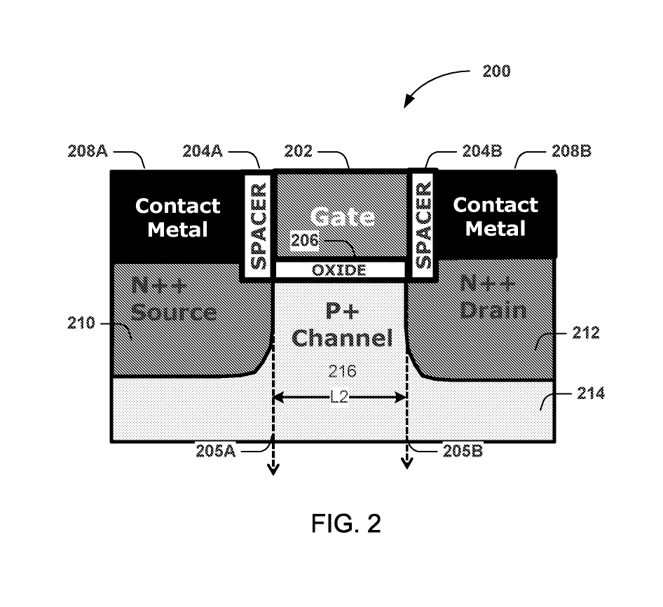

FIG. 2 schematically illustrates a cross section of an exemplary semiconductor device 200, in accordance with some embodiments. Referring to FIG. 2, a source region 210 and a drain region 212 are disposed on a semiconductor substrate 214 that includes any semiconductor material known to a person of ordinary skill in the art, e.g., silicon. Semiconductor substrate 214 may have any conductivity type, e.g., n-type or p-type and have any bulk resistivity, e.g., 2 ohm-cm to 100 ohm-cm. Semiconductor substrate 214 may be an epitaxial material over a more heavily doped substrate as is known to a person of ordinary skill in the art. A doping density of semiconductor substrate 214, source region 210, or drain region 212, as well as a thickness of oxide 206 and other parameters may affect a threshold voltage Vₜₕ of device 200.

Source region 210 may be disposed on semiconductor substrate 214 and extend to side edge 205A of gate 202. Similarly, drain region 212 may be disposed on semiconductor substrate 214 and extend to side edge 205B of gate 202. Source region 210 and drain region 212 may have any conductivity type known to a person of ordinary skill in the art. In the embodiment shown in FIG. 2, semiconductor substrate 214 may have a first conductivity type, e.g., p-type, and source and drain regions 210 and 212, respectively, may have a second conductivity type different or opposite that of substrate 214, e.g., n-type, to form a n-type metal oxide semiconductor device (NMOS). In an embodiment in which device 200 is a p-type device (PMOS), substrate 214 may include a well (not shown) on which source region 210 and drain region 212 are formed through impurity implantation, as is well known to a person of ordinary skill in the art.

A gate oxide 206 may be disposed between substrate 214 and gate 202. Gate oxide 206 may be a dielectric, e.g., silicon dioxide, oxynitride, or a high-k material, which serves to separate gate 202 from the underlying semiconductor substrate 214. A spacer 204A may be disposed along edge 205A of gate 202 to separate gate 202 from metal contact 208A. Similarly, a spacer 204B may be disposed along edge 205B of gate 202 to separate gate 202 from metal contact 208B. Spacers 204A and 204B may include one or more layers of silicon dioxide and/or silicon nitride although any material known to a person of ordinary skill in the art may also be used. Spacers 204A and 204B may have any dimensions appropriate for their application.

A voltage difference between source region 210 and the gate stack 202 in excess of the threshold voltage Vth may create a channel region 216 and then a positive voltage difference between source region 210 and drain region 212 will attract carriers from source region 210 to drain region 212 to generate current flow as is well known to a person of ordinary skill in the art.

In an embodiment, device 200 may be fabricated by providing a substrate 214, growing a field oxide over substrate 214, etching the oxide, and implanting dopants to create source region 210 and drain region 212. Metal may be deposited over an oxide layer to create gate 202. Where the device is a p-type device, a well (not shown) may first be created that has a conductivity type different from or opposite to the conductivity type of the substrate. In some embodiments, substrate 214 may have a p-type conductivity type while source region 210 and drain region 212 may be an n-type conductivity type. Methods for fabricating device 200 are well known to those of ordinary skill in the art.

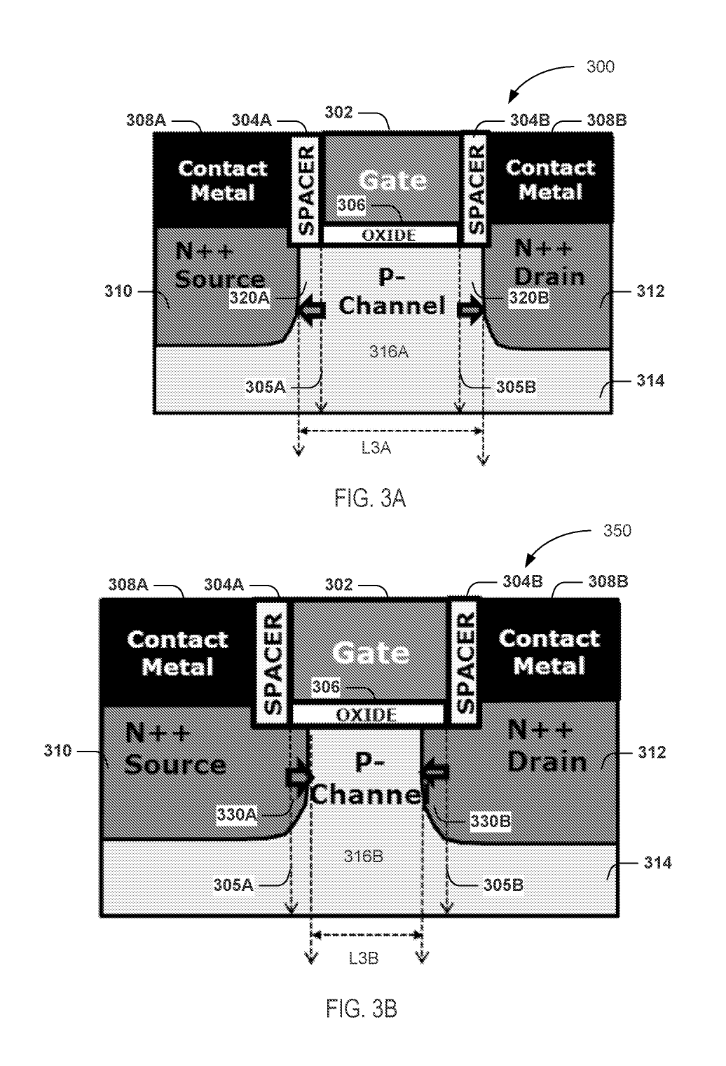

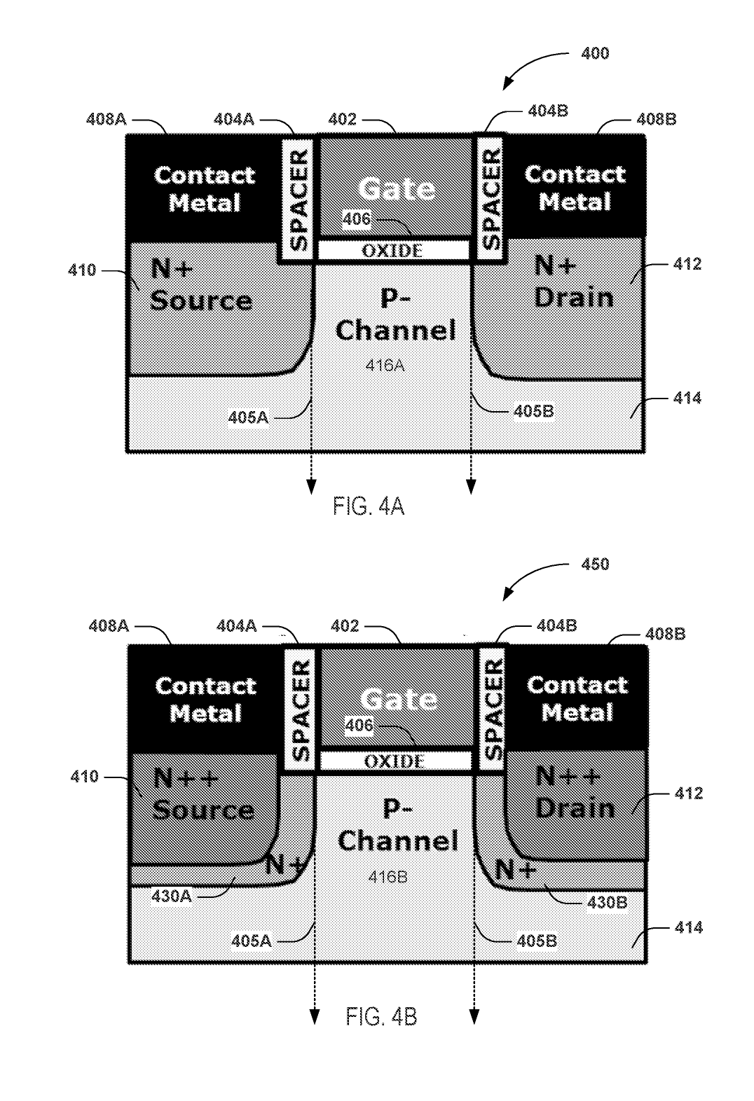

FIG. 3A schematically illustrates a cross section of an exemplary semiconductor device 300, in accordance with some embodiments. FIG. 3B schematically illustrates a cross section of an exemplary semiconductor device 350, in accordance with some embodiments. Referring to FIGS. 3A and 3B, a source region 310 and a drain region 312 are disposed on a semiconductor substrate 314 that includes any semiconductor material known to a person of ordinary skill in the art, e.g., silicon. Semiconductor substrate 314 may have any conductivity type, e.g., n-type or p-type and have any bulk resistivity, e.g., 2 ohm-cm to 100 ohm-cm. In the embodiment shown in FIGS. 3A and 3B, semiconductor substrate 314 may have a first conductivity type, e.g., p-type. A person of ordinary skill in the art should recognize that semiconductor substrate 314 may have any conductivity type including n-type and p-type depending on application. A doping density of semiconductor substrate 314, source region 310, or drain region 312 as well as a thickness of oxide 306 and/or other parameters may affect a threshold voltage Vₜₕ of devices 300 and 350.

Source region 310 and drain region 312 may be disposed on semiconductor substrate 314 by means known to those of ordinary skill in the art, e.g., by implanting dopants or epitaxial growth of doped materials in the unmasked areas of the semiconductor substrate 314.

Source region 310 and drain region 312 may have dopants of any conductivity type, e.g., n-type or p-type, in any density, e.g., 1e19 ions/cm³, known to a person of ordinary skill in the art. In the embodiment shown in FIGS. 3A and 3B, semiconductor substrate 314 may have a first conductivity type, e.g., p-type, and source and drain regions 310 and 312, respectively, may have a second conductivity type different or opposite that of substrate 314, e.g., n-type, to form a n-type metal oxide semiconductor device (NMOS). In an embodiment in which devices 300 or 350 are p-type devices, e.g., PMOS devices, substrate 314 may include a well (not shown) on which source region 310 and drain region 312 are formed, as is well known to a person of ordinary skill in the art.

A gate oxide 306 may be disposed between substrate 314 and gate 302. Gate oxide 306 may be a dielectric, e.g., polysilicon, which serves to separate or insulate gate 302 from the underlying semiconductor substrate 314. A spacer 304A may be disposed along edge 305A of gate 302 to separate gate 302 from metal contact 308A coupled, in turn, to source region 310. Similarly, a spacer 304B may be disposed along edge 305B of gate 302 to separate or insulate gate 302 from metal contact 308B coupled, in turn, to drain region 312. Spacers 304A and 304B may include one or more layers of silicon dioxide and/or silicon nitride although any material known to a person of ordinary skill in the art may also be used. Spacers 304A and 304B may have any dimensions appropriate for their application.

In an embodiment, source region 310 of device 300 may be disposed on semiconductor substrate 314 extending short of side edge 305A to create an underlap sub region 320A. In some embodiments, underlap sub-region 320A may be defined as a distance between edge 305A and an edge of source region 310. Source region 310 may only extend partway to side edge 305A to create underlap sub region 320A. Similarly, drain region 312 of device 300 may be disposed on semiconductor substrate 314 extending short of side edge 305B to create underlap sub region 320B. In some embodiments, underlap sub-region 320B may be defined as a distance between edge 305B and an edge of drain region 312. Put differently, drain region 312 may only extend partway to side edge 305B to create underlap sub region 320B. Source region 310 and drain region 312, thus, may underlap gate 302. In an embodiment, source region 310 and drain region 312 may underlap gate 302 by an underlap defined by a width of sub regions 320A and 320B. Underlap sub regions 320A and 320B may increase the lateral distance between source region 310 and drain region 312.

In an embodiment, channel region 316A may extend into sub regions 320A and 320B to lengthen channel region 316A to a lateral dimension L3A. Channel region 316A, therefore, is longer relative to channel 216 having a lateral dimension L2 shown in FIG. 2. The increased lateral dimension L3A of channel region 316A may advantageously increase the threshold voltage Vₜₕ necessary to operate device 300. In an embodiment, source region 310 of device 350 may be disposed on semiconductor substrate 314 extending long of side edge 305A to create an overlap sub region 330A. Similarly, drain region 312 of device 350 may be disposed on semiconductor substrate 314 extending long of side edge 305B to create an overlap sub region 330B. Source region 310 and drain region 312, thus, may overlap gate 302 by overlap sub regions 330A and 330B.Overlap sub regions 330A and 330B may decrease the lateral distance between source region 310 and drain region 312.

In an embodiment, channel region 3163 may decrease by overlap regions 330A and 330B to laterally shorten channel to lateral dimension L3B. Channel region 316B, therefore, is shorter relative to channel 216 or 316A having a lateral dimension L2 shown in FIG. 2 or a lateral dimension L3A shown in FIG. 3A, respectively. The shortened lateral dimension L3B of channel 316B may advantageously decrease the threshold voltage Vₜₕ necessary to operate device 350.

In an embodiment, devices 300 and 350 may be fabricated by providing a substrate 314, growing a field oxide over substrate 314, etching the oxide, and implanting dopants using known masks to create source region 310 and drain region 312 as is well known to a person of ordinary skill in the art. Metal may be deposited over a polysilicon layer to create gate 302. Where the device is a p-type device, a well may first be created that has a conductivity type different from or opposite to the conductivity type of the substrate. Methods for fabricating devices 300 and 350 are well known to those of ordinary skill in the art.

FIG. 4A schematically illustrates a cross section of an exemplary semiconductor device, in accordance with some embodiments. FIG. 4B schematically illustrates a cross section of an exemplary semiconductor device, in accordance with some embodiments. Referring to FIGS. 4A and 4B, a source region 410 and a drain region 412 are disposed on a semiconductor substrate 414 that, like semiconductor substrates 214 and 314, may include any semiconductor material known to a person of ordinary skill in the art, e.g., silicon. Semiconductor substrate 414 may have any conductivity type, e.g., n-type or p-type and have any bulk resistivity, e.g., 2 ohm-cm to 100 ohm-cm. In the embodiment shown in FIGS. 4A and 48, semiconductor substrate 414 may have a first conductivity type, e.g., p-type. A person of ordinary skill in the art should recognize that semiconductor substrate 414 may have any conductivity type including n-type and p-type depending on application. A doping density of semiconductor substrate 414 as well as a thickness of oxide 406 and/or other parameters may affect a threshold voltage Vₜₕ of devices 400 and 450.

Source region 410 and drain region 412 may be disposed on semiconductor substrate 414 by any means known to those of ordinary skill in the art, e.g., by implanting dopants or epitaxial growth of doped material in the unmasked areas of the semiconductor substrate 414.

Source region 410 and drain region 412 may have dopants of any conductivity type in any density, e.g., 1e19 to 5e19 ions/cm³, known to a person of ordinary skill in the art. In the embodiments shown in FIGS. 4A and 4B, source region 410 and drain region 412 may have a second conductivity type, e.g., n-type, opposite to the first conductivity type, e.g., p-type, of semiconductor substrate 414.

A gate oxide 406 may be disposed between substrate 414 and gate 402. Gate oxide 406 may be a dielectric, e.g., polysilicon, which serves to separate or insulate gate 402 from the underlying semiconductor substrate 414. A spacer 404A may be disposed along edge 405A of gate 402 to separate gate 402 from metal contact 408A coupled, in turn, to source region 410. Similarly, a spacer 404B may be disposed along edge 405B of gate 402 to separate or insulate gate 402 from metal contact 408B coupled, in turn, to drain region 412. Spacers 404A and 404B may include one or more layers of silicon dioxide and/or silicon nitride although any material known to a person of ordinary skill in the art may also be used. Spacers 404A and 404B may have any dimensions appropriate for their application.

In an embodiment, source region 410 of device 400 may be disposed on semiconductor substrate 414 extending to side edge 405A. Similarly, drain region 412 of device 400 may be disposed on semiconductor substrate 414 extending to side edge 405B. Source region 410 and drain region 412 may include a doping density between 1e19 to 1e20 ions/cm³ to increase the threshold voltage Vₜₕ necessary to operate device 400 relative to e.g., device 200 shown in FIG. 2. Lowering a doping density of the source region 410 and the drain region 412 relative to, e.g., device 200 shown in FIG. 2, may result in increasing a threshold voltage Vₜₕ, decreasing a drain saturation current I_{dsat}, and improving a subthreshold swing (SS) and drain-induced barrier lowering (DIBL) parameters. Lightly doping source region 410 and drain region 412 may advantageously improve power consumption of device 400.

Device 450 may include a source region 410 that, in turn, may include a source sub region 430A and drain region 412 that, in turn, may include a drain sub region 430B. In an embodiment, source sub region 430A may substantially surround source region 410 such that together, source region 410 and source sub region 430A extend to side edge 405A of device 450. In an embodiment, source region 410 and source sub region 430A may have a first conductivity type, e.g., n-type. Source region 410, however, may have a doping density, e.g., 5e19 to 1e21 ions/cm³, higher than a doping density, e.g., 1e19 to 5e19 ions/cm³, of source sub region 430A.

Similarly, drain sub region 430E may substantially surround drain region 412 such that together, drain region 412 and drain sub region 430B extend to side edge 405B of device 450. In an embodiment, drain region 412 and drain sub region may have a first conductivity type, e.g., n-type. Drain region 412, however, may have a doping density, e.g., 5e19 to 1e21 ions/cm³, higher than a doping density, e.g., 1e19 to 5e19 ions/cm³, of drain sub region 430B. Creating such a doping density profile with a higher doping density at source and drain regions 410 and 412 relative to the lower doping density at source and drain sub regions 430A and 4303, may result in device 400 having a higher threshold voltage Vₜₕ and a lower external resistance, e.g., 200 oh-um, compared to a device without such a doping density profile.

A person of ordinary skill in the art should recognize that the techniques described herein may apply to devices other than bulk CMOS, e.g., FinFETs, nanowire FETs, or any other CMOS structures that have doped source/drain regions.

Table 1 below indicates the effectiveness of various approaches to increasing the threshold voltage Vₜₕ of a semiconductor device according to various embodiments.

TABLE 1

| | | Process | | Usefulness |
|---|---|---|---|---|
| | DIBL, SS, | development | | for a |
| Approach | SCE | cost | Variation | scaled device |
| High channel | Effective | Standard | Large | Thin-body |
| doping | | implant and | variation | lowers |
| | | epitaxial | | effectiveness |
| | | process | | |
| Work func- | No | Needs work | Variation is | Effective |
| tion using | change | function to | difficult to | for a |
| different | | metal | avoid partic- | scaled device |
| metal | | targeting | ularly for | |
| process or | | process | devices having | |
| thickness | | development | more than a | |
| | | | single threshold | |
| | | | voltage target | |
| Varying | Effective | Standard | Small | Particularly |
| source/drain | | implant and | variation | effective for |
| design to | | epitaxial | | scaled devices |
| include sub | | process | | |
| regions | | | | |

Where:

DIBL refers to drain-induced barrier lowering;

SS refers to subthreshold swing; and

SCE refers to short channel effect.

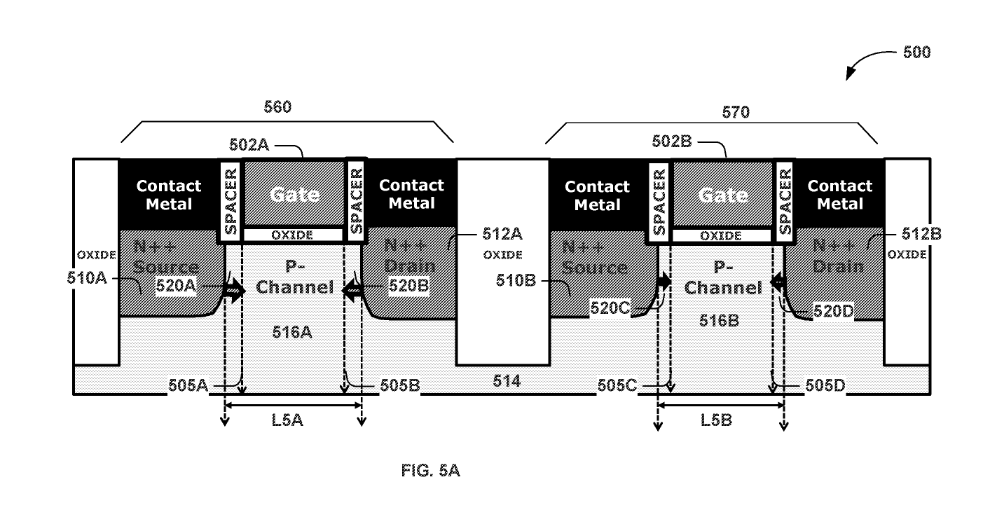

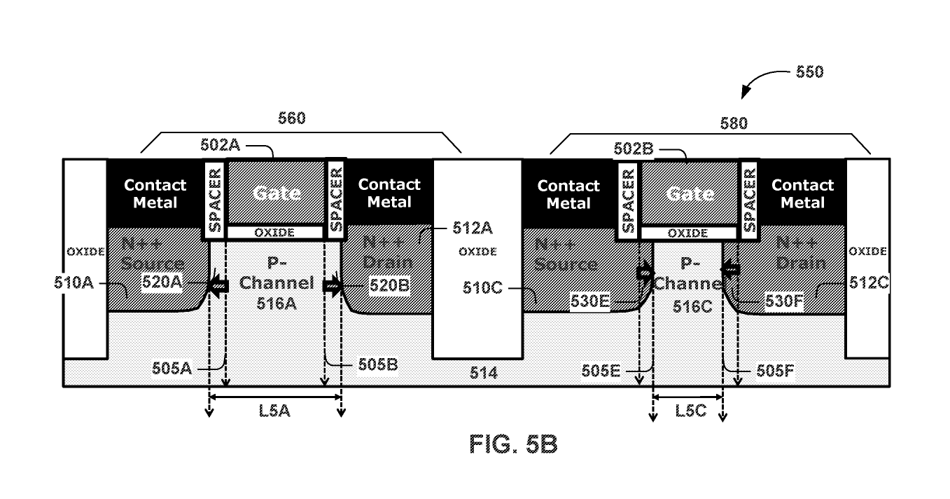

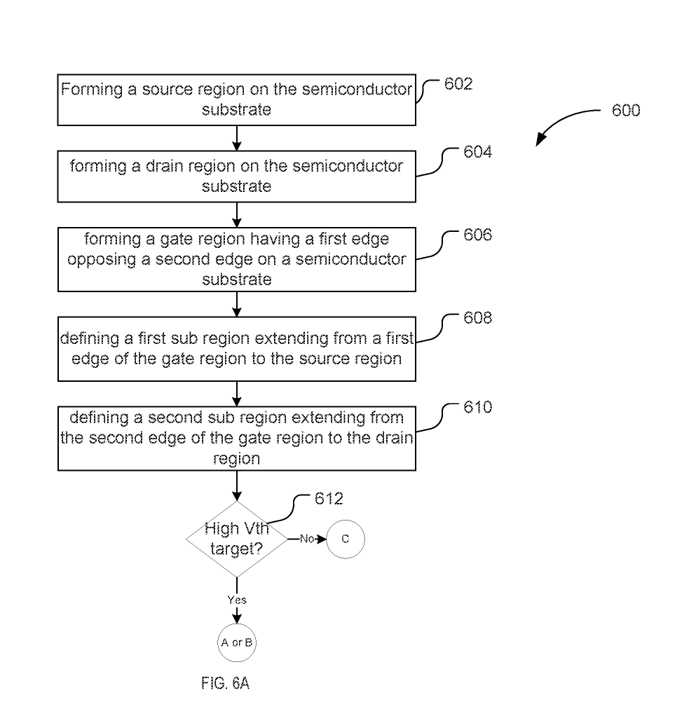

FIG. 5A schematically illustrates a cross section of an exemplary semiconductor integrated circuit 500, in accordance with some embodiments. FIG. 5B schematically illustrates a cross section of an exemplary semiconductor integrated circuit 550. Referring to FIGS. 5A and 5B, integrated circuit 500 includes a first device 560 and a second device 570. First device 560 and second device 570 may be metal oxide semiconductor devices. Although both first device 560 and second device 570 are shown as NMOS devices, it is possible for first device 560 to be an NMOS device and for second device 570 to be a PMOS device.

First device 560 may include a first gate stack 502A disposed on a semiconductor substrate 514 and having a first edge 505A opposing a second edge 505B. A first source region 510A and a first drain region 512A are disposed on semiconductor substrate 514. A first sub region 520A may extend from first edge 505A of first gate stack 502A to first source region 510A. A second sub region 520B may extend from a second edge 5053 of first gate stack 502A to first drain region 512A. In some embodiments, first sub-region 520A may be defined as a first distance between edge 505A and an edge of source region 510.E and second sub-region 520B may be defined as a second distance different from the first distance and between edge 505B and an edge of drain region 512A.

Second device 570 may include a second gate stack 502B disposed on a semiconductor substrate 514 and having a third edge 505C opposing a fourth edge 505D. A second source region 510B and a second drain region 512B are disposed on semiconductor substrate 514. A third sub region 520C may extend from third edge 505C of second gate stack 502B to second source region 510B. A fourth sub region 520D may extend from a fourth edge 505D of second gate stack 502B to second drain region 512B. In some embodiments, third sub-region 520C may be defined as a third distance between edge 505C and an edge of source region 510B and fourth sub-region 520D may be defined as a fourth distance different from the third distance and between edge 505D and an edge of drain region 5123.

First source region 510A, first drain region 512A, second source region 510B, and second drain region 512B may have any conductivity type known to a person of ordinary skill in the art, including an n-type or p-type conductivity type. Likewise, semiconductor substrate 514 may have any conductivity type known to a person of ordinary skill in the art, including an n-type or p-type conductivity type. As shown in FIG. 5A, semiconductor substrate 514 may have a p-type conductivity type while first source region 510A, first drain region 512A, second source region 510B, and second drain region 512B may have an n-type conductivity type where first device 560 and second device 570 are NMOS devices. A person of ordinary skill in the art should recognize that first device 560 and second device 570 may be NMOS or PMOS devices, or a combination of NMOS and PMOS devices.

While integrated circuit device 500 is shown with only first device 560 and second device 570, a person of ordinary skill in the art should recognize that integrated circuit device 500 may include any number of devices 560 and 570 with each device having any conductivity type known to a person of ordinary skill in the art,

First device 560 and second device 570 may be manufactured using substantially similar processes using a known set of design rules, e.g., 45 nm, 22 nm, 14 nm, 10 nm, 7 nm, and the like, for substantially similar applications, e.g., logic, input/output and the like. By doing so, both first device 560 and second device 570 may have a similar gate length, size, pitch, or other characteristics with the exception of the sub-regions or distances 520A, 520B, 520C, and/or 520D as described herein.

For example, both first device 560 and second device 570 may be logic devices manufactured using a same 10 nm node semiconductor process, but first device 560 may have a distance 520A that is different, e.g., longer, from a distance 520C in second device 570. Sub region or distance 520A may be different from sub region or distance 520C by more than mere process variation. Put differently, sub region or distance 520A of first device 560 may have a dimension that is intentionally longer than or intentionally shorter than a similar dimension of sub region or distance 520C of second device 570. A person of ordinary skill in the art should recognize that the difference between sub region or distance 520A and sub region or distance 520C is more than mere process variation and designed intentionally in such a way as to result in devices that operate with predetermined threshold voltages as explained in more detail above. In an embodiment, sub region or distance 520A of first device 560 may be greater than sub region or distance 520C of second device 570 by a distance that is greater than any distance introduced due to process variations. For example, sub region or distance 520A of first device 560 may be greater than sub region or distance 520C of second device 570 by at least 3 nm for both 10 nm and 7 nm node semiconductor processes.

First device 560 may be manufactured to be spatially close to second device 570. In an embodiment, first device 560 may be formed immediately next to second device 570 or first device 560 may be formed on a same logic or functional unit of an integrated circuit.

In an embodiment, all low threshold voltage Vₜₕ (both NMOS and PMS) transistors or devices may be on a same gate for improved performance.

In an embodiment, all high threshold Vₜₕ (both NMOS and PMOS) transistors or devices may be on a same gate for low leakage.

In an embodiment, for a given gate, some or all of the NMOS transistors or devices can be low threshold voltage Vₜₕ transistors for improved performance of the output transition from hi to low.

In an embodiment, for a given gate, some or all of the PMOS transistors or devices can be low threshold voltage Vₜₕ transistors for improved performance of the output transition from low to high.

In an embodiment, for a given gate, some or all of the NMOS transistors or devices can be high threshold voltage Vₜₕ transistors for low leakage control in the output high condition.

In an embodiment, for a given gate, some or all of the PMOS transistors or devices can be high threshold voltage Vₜₕ transistors for low leakage control in the output low condition.

For these transistors or devices, the source to drain distance may be the same but the gate to source (or gate to drain) distances may vary to create low and high threshold voltage Vₜₕ transistors.

In an embodiment shown in FIG. 5A, first channel region 516A may extend over first sub region 520A and second sub region 520B such that first sub region 520A and second sub region 520B define, at least in part, a first threshold voltage Vₜₕ₁ of first device 560.

Similarly, a second channel region 516B may extend over third sub region 520C and fourth sub region 520D such that third sub region 520C and fourth sub region 520D define, at least in part, a second threshold voltage Vₜₕ₂ of second device 570. First threshold voltage Vₜₕ₁ may be different from the second threshold voltage Vₜₕ₂ due to a length of first and second channel regions 516A and 516B. In an embodiment, channel region 516A may have a longer lateral dimension L5A relative to lateral dimension L5B of channel region 516B, which may result in threshold voltage Vₜₕ₁ being different from or higher than second threshold voltage Vₜₕ₂.

In an embodiment shown in FIG. 5B, device 580 includes a source region 510C that extends long of side edge 505E to create an overlap sub region 530E. Similarly, drain region 512C extends long of side edge 505F to create an overlap sub region 530F. Source region 510C and drain region 512C, thus, may overlap gate 502B by overlap sub regions 530E and 530F. Overlap sub regions 530E and 530F may decrease the lateral distance between source region 510C and drain region 512C to thus advantageously decrease Vₜₕ₃ of device 580.

In an embodiment, channel region 516C may decrease by overlap regions 530E and 530F to laterally shorten channel by lateral dimension L5C. Channel region 516C, therefore, is shorter relative to channel 516A. The shortened lateral dimension L5C of channel 516C decreases the threshold voltage Vₜₕ₃ necessary to operate device 580. First threshold voltage Vₜₕ₁ may be different from third threshold voltage Vₜₕ₃ due to a length of first and third channel regions 516A and 516C of devices 560 and 580, respectively. In an embodiment, channel region 516A may have a longer lateral dimension L5A relative to lateral dimension L5C of channel region 516C, which may result in threshold voltage Vₜₕ₁ being different, e.g., higher, from second threshold voltage Vₜₕ₃.

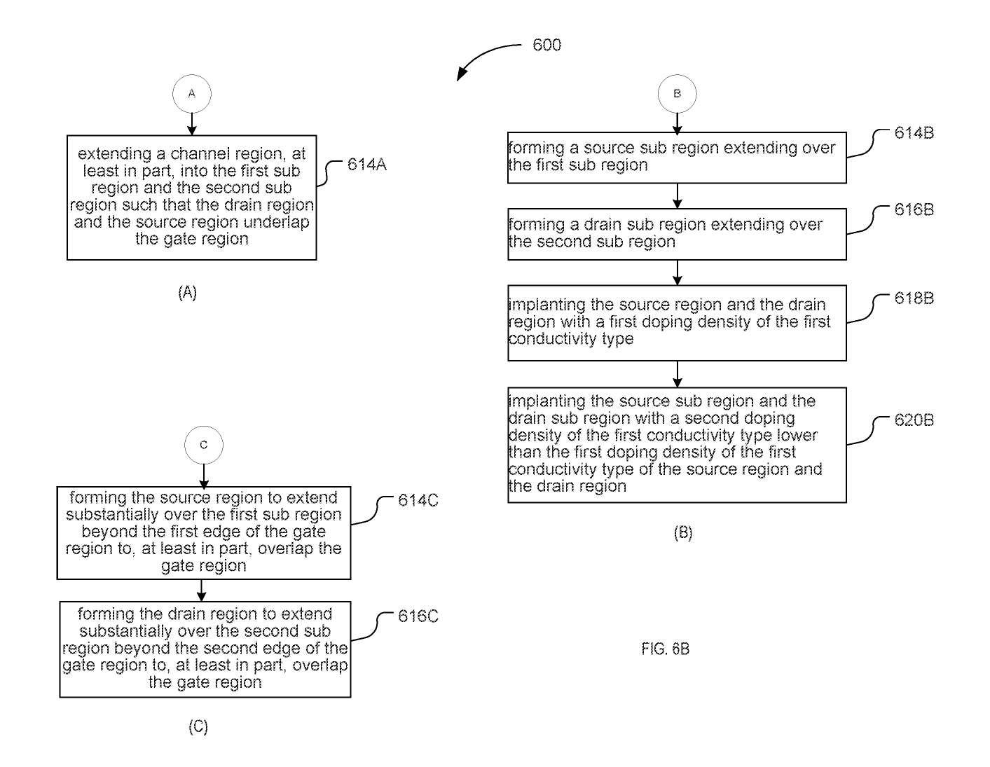

FIGS. 6A-6B schematically illustrate a flow diagram for a method 600 of fabricating semiconductor devices with various threshold voltages, in accordance with some embodiments. The method 600 may comport with various techniques and configurations described in connection with FIGS. 2-5B and vice versa, according to various embodiments.

At 602, method 600 may include forming a source region on the semiconductor substrate (e.g., die 102). The source region may have a first conductivity type, e.g., n-type. Forming the source region may involve patterning, etching, and/or masking the substrate and implanting impurities into the substrate as is well known to a person of ordinary skill in the art.

At 604, method 600 may further include forming a drain region on the substrate. The drain region may have a first conductivity type, e.g., n-type. Forming the drain region may involve patterning, etching, and/or masking the substrate and implanting impurities into the substrate as is well known to a person of ordinary skill in the art.

At 606, method 600 may further include forming a gate stack having a first edge opposing a second edge on the semiconductor substrate. Forming the gate stack may involve forming an oxide layer 306 with a dielectric material and/or forming openings in the oxide layer to create gate electrodes as is well known to a person of ordinary skill in the art. Openings may be formed using any suitable technique including patterning such as lithography and/or etch.

At 608, method 600 may define a first sub region extending from a first edge of the gate stack to the source region.

At 610, method 600 may define a second sub region extending from the second edge of the gate stack to the drain region.

At 612, method 600 may determine whether a high threshold voltage is targeted.

In an embodiment in which a device is desired to have a high threshold voltage, at 614A, method 600 may extend a channel region into the first sub region and the second sub region such that the drain region and the source region underlap the gate stack. Put differently, method 600 may form the source region and the drain region to underlap the gate stack and lengthen the channel region into the first and second sub regions to thereby increase the threshold voltage during operation.

In an alternative embodiment in which a device is desired to have a high threshold voltage, at 614B, method 600 may form a source sub region extending over the first sub region.

At 616B, method 600 may form a drain sub region extending over the second sub region.

At 618B, method 600 may implant the source region and the drain region with a first doping density of a conductivity type, e.g., n-type.

At 620B, method may implant the source sub region and the drain sub region with a second doping density of a conductivity type, e.g., n-type. The second doping density may be lower than the first doping density of the source and drain regions. In an embodiment in which a device is desired to have a low threshold voltage, at 614C, method 600 may form the source region to extend substantially over the first sub region beyond the first edge of the gate stack to overlap the gate stack.

At 616C, method $00 may form the drain region to extend substantially over the second sub region beyond the second edge of the gate stack to overlap the gate stack.

Method 600 may be used to form semiconductor devices on an integrated circuit that have various threshold voltages. For example, the actions described in method 600 at 600-610 and 614A may be used to create a first device on an integrated circuit while the actions described in method 600 at 600-610 and 614B-620B and/or 614C-616C may be used to create second or third devices within the same integrated circuit depending on various design parameters including desired speed, power profiles, and the like.

Various operations are described as multiple discrete operations in turn, in a manner that is most helpful in understanding the claimed subject matter. However, the order of description should not be construed as to imply that these operations are necessarily order dependent. Embodiments of the present disclosure may be implemented into a system using any suitable hardware and/or software to configure as desired.

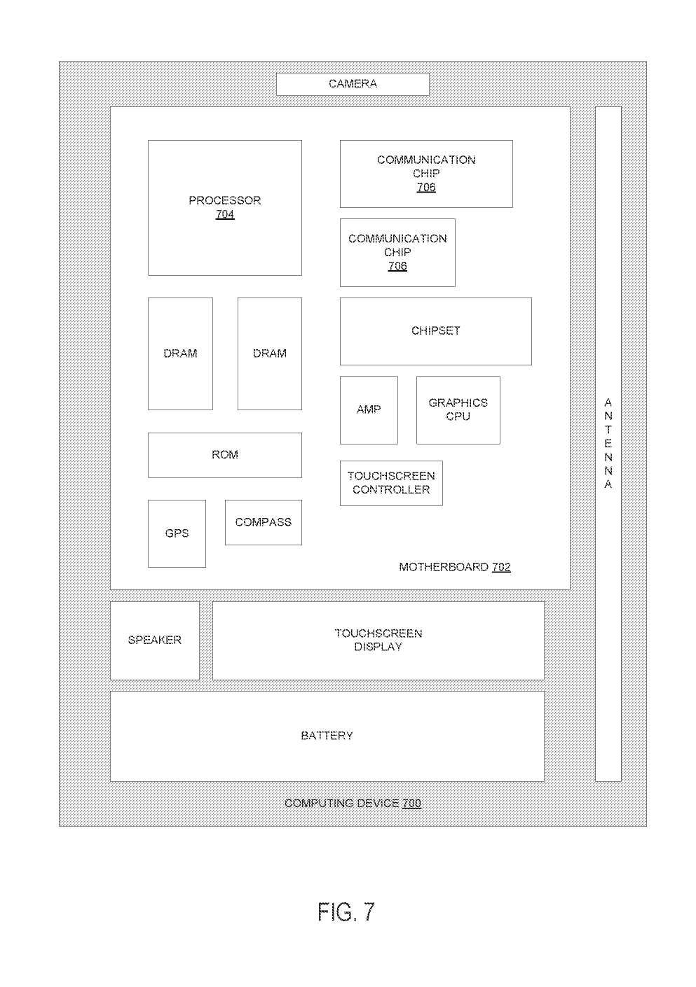

FIG. 7 schematically illustrates an example system (e.g., computing system 700) that may include integrated circuits having transistor devices with various threshold voltages as described herein, in accordance with some embodiments.

A motherboard 702 may include a number of components, including but not limited to a processor 704 and at least one communication chip 706. Processor 704 may be physically and electrically coupled to motherboard 702. In some implementations, the at least one communication chip 706 may also be physically and electrically coupled to motherboard 702. In further implementations, communication chip 706 may be part of processor 704.

Depending on its applications, computing device 700 may include other components that may or may not be physically and electrically coupled to motherboard 702. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

Communication chip 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 706 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. Communication chip 706 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. Communication chip 706 may operate in accordance with other wireless protocols in other embodiments.

Computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE,

CPRS, CDMA, WiMAX, LTE, Ev-DO, and others.

Processor 704 of computing device 700 may include a die (e.g., die 102 of FIGS. 1A-1B) having transistors structures with modulated threshold voltage using workfunction modifying layers as described herein. For example, die 102 of FIGS. 1A-1B may be mounted in a package assembly that is mounted on the motherboard 702. The term “processor” may refer to any device or portion of a device that processes electronic data from registers and/or memory to transform that electronic data into other electronic data that may be stored in registers and/or memory.

Communication chip 706 may also include a die (e.g., die 102 of FIGS. 1A-1B) having transistors structures with varying threshold voltages using drain or source region improvements as described herein. In further implementations, another component (e.g., memory device or other integrated circuit device) housed within the computing device 700 may contain a die (e.g., die 102 of FIGS. 1A-1B) having transistors structures with varying threshold voltages using drain or source region improvements as described herein.

In various implementations, the computing device 700 may be a mobile computing device, laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

### EXAMPLES

According to various embodiments, the present disclosure describes a semiconductor device.

Example 1 of the integrated circuit may include a first semiconductor device and a second semiconductor device disposed on the semiconductor substrate and having the same pitch. The first semiconductor device includes a first gate stack comprising a first gate dielectric and a first gate electrode and a first source region. The second semiconductor device includes a second gate stack comprising a second gate dielectric and a second gate electrode and a second source region. The first source region and the first gate stack are separated by a first distance. The second source region and the second gate stack are separated by a second distance and the first distance is different than the second distance.

Example 2 may include the integrated circuit of Example 1 wherein the first semiconductor device further comprises a first drain region, wherein the second semiconductor device further comprises a second drain region, wherein the first drain region and the first gate stack are separated by a third distance, wherein the second drain region and the second gate stack are separated by a fourth distance, and wherein the third distance is different than the fourth distance.

Example 3 may include the integrated circuit of Examples 1 or 2 wherein the first semiconductor device further comprises a first channel region disposed underneath the first gate stack.

Example 4 may include the integrated circuit of Examples 3 wherein the first channel region extends between the first source region and the first drain region such that the first source region underlaps the first gate stack by the first distance and the first drain region underlaps the first gate stack by the third distance.

Example 5 may include the integrated circuit of Examples 1 or 2 wherein the second semiconductor device further comprises a second channel region disposed underneath the second gate stack.

Example 6 may include the integrated circuit of Example 5 wherein the second channel region extends between the second source region and the second drain region such that the second source region underlaps the second gate stack by the second distance and the second drain region underlaps the second gate stack by the fourth distance.

Example 7 may include the integrated circuit of Example 5 wherein the second source region at least in part overlaps the second gate stack and wherein the second drain region at least in part overlaps the second gate stack.

Example 8 may include the integrated circuit of Example 2 wherein the first source region at least in part overlaps the first gate stack by extending beyond the first edge and wherein the first drain region at least in part overlaps the first gate stack by extending beyond the third edge.

Example 9 may include the integrated circuit of Example 2 wherein the first source region has a first source sub region extending over the first distance and wherein the first drain region has a first drain sub region extending over the third distance.

Example 10 may include the integrated circuit of Example 9 wherein the first source region and the first drain region have a first doping density of a first conductivity type and wherein the first source sub region and the first drain sub region have a second doping density of the first conductivity type lower than the first doping density of the first conductivity type of the first source region and the first drain region.

Example 11 of a circuit may include a first device and a second device disposed on a semiconductor substrate. The first device may include a first gate stack having a gate length and a first source region. The second device may include a second gate stack having the same gate length and a second source region. The first gate stack and the first source region are separated by a first distance and the second gate stack and the second source region are separated by a second distance different from the first distance.

Example 12 may include the circuit of Example 11 wherein the first device further includes a first channel region disposed on the semiconductor substrate substantially underneath the first gate stack and wherein the second device further includes a second channel region disposed on the semiconductor substrate substantially underneath the second gate stack.

Example 13 may include the circuit of Example 12 wherein the first device further includes a first drain region, wherein the first channel region is wider than first gate stack, and wherein the first drain region and first source region underlap the first gate stack.

Example 14 may include the circuit of Example 13 wherein the first source region at least in part overlaps the first gate stack and wherein the first drain region at least in part overlaps the first gate stack.

Example 15 may include the circuit of Example 13 a first source sub region extending between the first gate stack and the first source region and a first drain sub region extending between the first gate stack and the first drain region.

Example 16 may include the circuit of Example 15 wherein the first source region and the first drain region have a first doping density of a first conductivity type and wherein the first source sub region and the first drain sub region have a second doping density of the first conductivity type lower than the first doping density of the first conductivity type of the first source region and the first drain region.

Example 17 may include the circuit of Example 16 wherein the first conductivity type is an n-type.

Example 18 may include a computing device comprising a circuit board and a die coupled with the circuit board, the die including a first device and a second device disposed on a semiconductor substrate and having a same pitch. The first device may include a first gate stack comprising a first dielectric and a first gate electrode and a first source region. The second device may include a second gate stack comprising a second dielectric and a second gate electrode and a second source region. The first source region and the first gate stack are separated by a first distance. The second source region and the second gate stack are separated by a second distance. And the first distance is different than the second distance.

Example 19 may include the computing device of Example 18 wherein the first device further includes a first drain region and wherein the second device further includes a second drain region. Example 20 may include the computing device of Example 19 wherein the first drain region and the first source region underlap corresponding sides of the first gate stack by a first underlap distance and wherein the second drain region and the second source region underlap corresponding sides of the second gate stack by a second underlap distance different from the first underlap distance.

Example 21 may include the computing device of Examples 18 to 20, wherein the same pitch includes a same gate length.

Example 22 may include a method comprising forming a first device and a second device on a semiconductor substrate having a same pitch. Forming the first device further may include forming a first gate stack having a first gate dielectric and a first gate electrode and forming a first source region such a first distance separates the first source region from the first gate stack. Forming the second device further may include forming a second gate stack having a second gate dielectric and a second gate electrode and forming a second source region such a second distance separates the second source region from the second gate stack. The first distance is different from the second distance.

Example 23 may include the method of Example 22 wherein forming the first device further includes forming a first channel region on the semiconductor substrate extending between the first source region and the first drain region and wherein forming the second device further includes forming a second channel region extending between the second source region and the second drain region.

Example 24 may include the method of Example 23 wherein the first source region and the second source region have a first conductivity type and wherein the first channel region has a second conductivity type opposite a first conductivity type.

Example 25 may include the method of Examples 22 or 23 wherein forming the first device further includes forming a first source sub region over the first distance.

Example 26 may include the method of Examples 25 further comprising implanting the first source region with a first doping density of a first conductivity type and implanting the first source sub region with a second doping density of the first conductivity type lower than the first doping density of the first conductivity type of the first source region and first drain region.

Example 27 may include a method comprising forming a first device and a second device having a first gate length on a semiconductor substrate. Forming the first device may include forming a first gate stack having a first gate dielectric and a first gate electrode and forming a first source region separated from the first gate stack by a first distance. Forming the second device may include forming a second gate stack having a second gate dielectric and a second gate electrode and forming the second source region separated from the second gate stack by a second distance. The first distance may be different from the second distance.

Various embodiments may include any suitable combination of the above-described embodiments including alternative (or) embodiments of embodiments that are described in conjunctive form (and) above (e.g., the “and” may be “and/or). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claim& Rather, the scope is to be determined entirely by the following claims, which are to be construed in accordance with established doctrines of claim interpretation.

What is claimed is:

1. An integrated circuit, comprising:
a semiconductor substrate;
a first semiconductor device and a second semiconductor device disposed on the semiconductor substrate and having the same pitch;
the first semiconductor device including:
a first gate stack comprising a first gate dielectric and a first gate electrode; and
a first source region;
the second semiconductor device including:
a second gate stack comprising a second gate dielectric and a second gate electrode; and
a second source region;
wherein the first source region and the first gate stack are separated by a first distance;
wherein the second source region and the second gate stack are separated by a second distance; and
wherein the first distance is different than the second distance.

2. The integrated circuit of claim 2,
wherein the first semiconductor device further comprises a first drain region;
wherein the second semiconductor device further comprises a second drain region;
wherein the first drain region and the first gate stack are separated by a third distance;
wherein the second drain region and the second gate stack are separated by a fourth distance; and
wherein the third distance is different than the fourth distance.

3. The integrated circuit of claim 2, wherein the first semiconductor device further comprises a first channel region disposed underneath the first gate stack.

4. The integrated circuit of claim 3, wherein the first channel region extends between the first source region and the first drain region such that the first source region underlaps the first gate stack by the first distance and the first drain region underlaps the first gate stack by the third distance.

5. The integrated circuit of claim 2, wherein the second semiconductor device further comprises a second channel region disposed underneath the second gate stack.

6. The integrated circuit of claim 5, wherein the second channel region extends between the second source region and the second drain region such that the second source region underlaps the second gate stack by the second distance and the second drain region underlaps the second gate stack by the fourth distance.

7. The integrated circuit of claim 5,
wherein the second source region at least in part overlaps the second gate stack; and
wherein the second drain region at least in part overlaps the second gate stack.

8. The integrated circuit of claim 2,
wherein the first source region at least in part overlaps the first gate stack; and
wherein the first drain region at least in part overlaps the first gate stack.

9. The integrated circuit of claim 2,
wherein the first source region has a first source sub region extending over the first distance; and
wherein the first drain region has a first drain sub region extending over the third distance.

10. The integrated circuit of claim 9,
wherein the first source region and the first drain region have a first doping density of a first conductivity type; and
wherein the first source sub region and the first drain sub region have a second doping density of the first conductivity type lower than the first doping density of the first conductivity type of the first source region and the first drain region.

11. A circuit, comprising:
a first device and a second device disposed on a semiconductor substrate;
the first device including:
a first gate stack having a gate length; and
a first source region;
the second device including:
a second gate stack having the same gate length; and
a second source region;
wherein the first gate stack and the first source region are separated by a first distance; and
wherein the second gate stack and the second source region are separated by a second distance different from the first distance.

12. The circuit of claim 11,
wherein the first device further includes a first channel region disposed on the semiconductor substrate substantially underneath the first gate stack; and
wherein the second device further includes a second channel region disposed on the semiconductor substrate substantially underneath the second gate stack.

13. The circuit of claim 12,
wherein the first device further includes a first drain region;
wherein the first channel region is wider than first gate stack; and
wherein the first drain region and first source region underlap the first gate stack.

14. The circuit of claim 13,
wherein the first source region at least in part overlaps the first gate stack; and
wherein the first drain region at least in part overlaps the first gate stack.

15. The circuit of claim 13, wherein the first device further includes:
a first source sub region extending between the first gate stack and the first source region; and
a first drain sub region extending between the first gate stack and the first drain region.

16. The circuit of claim 15,
wherein the first source region and the first drain region have a first doping density of a first conductivity type; and
wherein the first source sub region and the first drain sub region have a second doping density of the first conductivity type lower than the first doping density of the first conductivity type of the first source region and the first drain region.

17. A computing device comprising:
a circuit board; and
a die coupled with the circuit board, the die including a first device and a second device disposed on a semiconductor substrate and having a same pitch;
wherein the first device includes:
a first gate stack comprising a first dielectric and a first gate electrode; and
a first source region; and
wherein the second device includes:
a second gate stack comprising a second dielectric and a second gate electrode; and
a second source region;
wherein the first source region and the first gate stack are separated by a first distance;
wherein the second source region and the second gate stack are separated by a second distance; and
wherein the first distance is different than the second distance.

18. The computing device of claim 17,
wherein the first device further includes a first drain region; and
wherein the second device further includes a second drain region.

19. The computing device of claim 18,
wherein the first drain region and the first source region underlap corresponding sides of the first gate stack by a first underlap distance; and
wherein the second drain region and the second source region underlap corresponding sides of the second gate stack by a second underlap distance different from the first underlap distance.

20. A method, comprising:
forming a first device and a second device on a semiconductor substrate having a same pitch;
wherein forming the first device further includes:
forming a first gate stack having a first gate dielectric and a first gate electrode; and
forming a first source region such a first distance separates the first source region from the first gate stack; and
wherein forming the second device further includes:
forming a second gate stack having a second gate dielectric and a second gate electrode; and
forming a second source region such a second distance separates the second source region from the second gate stack;
wherein the first distance is different from the second distance.

21. The method of claim 20,
wherein forming the first device further includes forming a first channel region on the semiconductor substrate extending between the first source region and the first drain region; and
wherein forming the second device further includes forming a second channel region extending between the second source region and the second drain region.

22. The method of claim 21,
wherein the first source region and the second source region have a first conductivity type; and
wherein the first channel region has a second conductivity type opposite a first conductivity type.

23. The method of claim 20, wherein forming the first device further includes forming a first source sub region over the first distance.

24. The method of claim 23, further comprising:
implanting the first source region with a first doping density of a first conductivity type; and
implanting the first source sub region with a second doping density of the first conductivity type lower than the first doping density of the first conductivity type of the first source region and first drain region.
